(19) United States
(12) Patent Application Publication
(10) Pub. No.: US 2020/0087526 A1
(43) Pub. Date: Mar. 19, 2020

(54) CROSSLINKABLE COMPOSITIONS BASED ON ELECTROACTIVE FLUORINATED COPOLYMERS

(71) Applicant: Arkema France, Colombes (FR)

(72) Inventors: Fabrice DOMINGUES DOS SANTOS, Paris (FR); Manuel HIDALGO, Brignais (FR); Thibaut SOULESTIN, Lyon (FR)

(73) Assignee: Arkema France, Colombes (FR)

(21) Appl. No.: 16/494,350

(22) PCT Filed: Apr. 12, 2018
(86) PCT No.: PCT/FR2018/050921

§ 371 Date: Sep. 16, 2019

(30) Foreign Application Priority Data
Apr. 14, 2017 (FR) 1753291

(51) Int. Cl. C09D 11/107; C09D 11/101; C09D 11/52; C08J 3/24; G03F 7/033; H01L 37/02; H01L 41/193; H01L 41/45; H01L 27/1159; H01L 27/11507

(52) U.S. Cl. CPC C09D 11/107; C09D 11/101; C09D 11/52; C08J 3/24; G03F 7/033; G03F 7/162; H01L 41/193; H01L 41/45; H01L 27/1159; H01L 27/11507; H01L 37/025

(57) ABSTRACT

The invention relates to crosslinkable compositions based on electroactive fluorinated copolymers, to crosslinked films obtained from such compositions and also to a process for preparing these films. The invention also relates to the use of said films as a dielectric layer in various (opto)electronic devices: piezoelectric, ferroelectric or pyroelectric devices.

### TECHNICAL FIELD

The present invention relates to crosslinkable compositions based on electroactive fluorinated copolymers, to crosslinked films obtained from such compositions and also to a process for preparing these films. The invention also relates to the use of said films as an electroactive layer in various (opto)electronic devices: piezoelectric, ferroelectric, pyroelectric, actuator or haptic devices, sensors, field-effect transistors, ferroelectric memories, or electromechanical microsystems.

### TECHNICAL BACKGROUND

“Electroactive polymers” or EAPs are polymers capable of converting mechanical or thermal energy into electricity or vice versa. Among these materials are fluorinated copolymers based on vinylidene fluoride (VDF) and trifluoroethylene (TrFE), which can optionally contain a third monomer such as chlorotrifluoroethylene (CTFE) or chlorofluoroethylene (CFE).

These polymers are formed as films, from an “ink” formulation consisting of a solution, in a solvent, of the electroactive fluorinated copolymer and, optionally, of other additives. During the production of electroactive devices, it may be necessary to render, according to a predefined pattern, a part or all of the film insoluble. This is due mainly to the fact that the electroactive fluorinated copolymer film constitutes only one layer of the whole of the device. Thus, other layers to be laid down on the layer of the electroactive fluorinated copolymer may have to be deposited on top by the solvent route, with the risk, if the electroactive fluorinated copolymer is not crosslinked, that it will be partially or completely dissolved (and therefore degraded) by the solvent present in the layer(s) deposited on top of it.

Crosslinked fluoropolymers are therefore required in order to form the layer of electroactive copolymer in an electroactive device.

Document WO 2015/128337 describes crosslinkable compositions comprising an electroactive fluoropolymer and an acrylic crosslinking agent. Said fluoropolymer (polymer (FC)) is crosslinkable due to the presence of repeating units derived from at least one functionalized hydrogenated monomer (monomer H′_{F}) comprising pendent side chains comprising unsaturated ether-type end groups. The crosslinkable compositions described herein are crosslinked by virtue of the presence of these crosslinkable fluoropolymers.

Document WO 2013/087500 also describes VDF-TrFE fluorinated copolymers made crosslinkable by the copolymerization of monomers comprising azide groups, with VDF and TrFE base monomers, it being possible for said fluorinated copolymers thus obtained to be crosslinked thermally or by UV irradiation.

Another solution has been proposed in document U.S. Pat. No. 6,680,357 which describes crosslinkable compositions comprising acrylic-modified copolymers based on VDF and on hexafluoropropylene (HFP), obtained by polymerization of said fluorinated copolymers with acrylic monomers.

In these situations, it is essential to chemically modify the electroactive fluorinated copolymer beforehand, which adds a step to the process for preparing the crosslinked polymer, with the risk of degrading the initial performance qualities of the electroactive fluorinated copolymer.

Other strategies provide for the direct crosslinking of the electroactive fluorinated copolymer by the radical route (peroxides) or by reaction with diamines, or else by electron beam or by X-rays; however, they have the drawback of an often chemically undesirable modification of the electroactive fluorinated copolymer which can lead to a loss of its properties.

Thus, there is a need to have available electroactive fluorinated copolymers which, after crosslinking of the composition which encompasses them, retain their electroactive properties, in particular their dielectric constant or their polarization, but also their mechanical properties, so as to provide optimal behaviour during their use in an (opto)electronic device, this being without these fluoropolymers crosslinking themselves, or being made crosslinkable by copolymerization with comonomers that can constitute repeating units which are reactive with respect to the crosslinking, or by chemical modification creating, on the polymer, sites which are reactive with respect to the crosslinking.

### SUMMARY OF THE INVENTION

A first objective of the invention is to provide a crosslinkable composition consisting of:

a) at least one electroactive fluorinated copolymer,

b) at least one (meth)acrylic monomer which is bifunctional or polyfunctional in terms of reactive double bonds,

c) at least one radical polymerization initiator,

d) at least one organic solvent, and

e) at least one additive chosen from the list: other (meth)acrylic monomers which are monofunctional in terms of reactive double bonds, agents which modify surface tension, rheology, ageing resistance, adhesion or colour, fillers and nanofillers.

According to one embodiment, said electroactive fluorinated copolymer is a copolymer of general formula P(VDF-TrFE), in which VDF represents units derived from vinylidene fluoride and TrFE represents units derived from trifluoroethylene.

According to one embodiment, the molar ratio of the VDF units to the TrFE units in the polymer is 50:50 to 85:15.

According to one embodiment, said electroactive fluorinated copolymer is a terpolymer of general formula P(VDF-TrFE-X), in which VDF represents units derived from vinylidene fluoride, TrFE represents units derived from trifluoroethylene, and X represents units derived from a third monomer bearing at least one fluorine atom, which can in particular be chosen from tetrafluoroethylene (TFE), chlorofluoroethylene (CFE), chlorotrifluoroethylene (CTFE), hexafluoropropylene (HFP), 3,3,3-trifluoropropene, 1,3,3,3-tetrafluoropropene (or 1234ze), 2,3,3,3-tetrafluoropropene (or 1234yf), 3-chloro-2,3,3-trifluoropropene (or 1233yf), 2-chloro-3,3,3-trifluoropropene (or 1233xd), hexafluoroisobutylene, perfluorobutylethylene, pentafluoropropene and mixtures thereof. Preferably, when it is present, said third monomer is chosen from CFE and CTFE.

According to one embodiment, the molar proportion of X units in the polymer is from 0.1% to 15%, preferably from 0.5% to 13%, and more particularly preferably from 1% to 12%.

Said (meth)acrylic monomer which is bifunctional or polyfunctional in terms of reactive double bonds can be a bifunctional or polyfunctional (meth)acrylic monomer or oligomer. As regards monomers that are of use in the invention, mention may be made of monomers and oligomers containing at least two reactive double bonds of (meth)acrylic type.

Another subject of the invention relates to a crosslinked film consisting of an electroactive fluorinated copolymer and of a crosslinked (meth)acrylic copolymer, said film being obtained from the crosslinkable composition according to the invention. Characteristically, said fluorinated copolymer is not crosslinked, and thus remains chemically non-modified, either by copolymerization with comonomers that can constitute repeating units which are reactive with respect to the crosslinking, or by chemical modification creating, on the polymer, sites which are reactive with respect to the crosslinking.

Another objective of the invention is to provide a process for preparing said crosslinked film, said process consisting in:
providing a crosslinkable composition according to the invention, as described above, in which said components (a), (b) and (c) and (e) are dissolved in said solvent (d) so as to obtain an ink,
depositing said ink on a support, a device or a part of a device which is (opto)electronic so as to form a film,
drying said film by partial or total evaporation of the solvent, and
crosslinking all or a part, depending on a predefined pattern, of said film by polymerization of the (meth)acrylic monomer(s),
in the case of the desired formation of a predefined pattern, developing said film in order to remove the non-crosslinked parts.

The invention also relates to the (opto)electronic devices comprising, as electroactive layer, at least one layer of the film prepared according to the abovementioned process.

The present invention makes it possible to overcome the drawbacks of the prior art. In particular, the invention makes it possible to obtain crosslinked films in which the electroactive polymers remain non-modified, because what forms a crosslinked network is the (meth)acrylic part which polymerizes and crosslinks after activation of the radical initiator. As a result, and without this constituting a limitation of the invention, it may be considered that the films according to the invention consist of a network of two polymers (fluorinated and (meth)acrylic), termed semi-interpenetrating network or semi-IPN, in which the fluorinated component is not crosslinked and therefore remains relatively unaffected from the point of view of the electrical properties. The (meth)acrylic network, itself, is crosslinked and provides the solvent resistance of the assembly. In other words, the invention provides a crosslinked film which comprises an acrylic crosslinked network within a non-crosslinked fluoropolymer system, the two systems being chemically independent. Surprisingly, this mixed non-crosslinked fluoropolymer/crosslinked acrylic polymer system makes it possible to obtain solvent-resistance behaviour. This strategy allows the stacking of layers of an (opto)electronic device on top of the layer comprising the electroactive fluorinated copolymer, without the solvents of these new layers dissolving or degrading the layer of electroactive fluorinated copolymer. This strategy also makes it possible to produce predefined patterns of the layer of electroactive fluorinated copolymers for producing complex (opto)electronic devices.

The use of electroactive fluorinated copolymers composed of VDF, of TrFE and optionally of a third monomer bearing fluorine atoms makes it possible to optimize the electroactive properties of the copolymer Specifically, these electroactive properties come from the presence of numerous carbon-fluorine (C—F) bonds which are strongly polarized, that is to say with an electron density greatly shifted on the fluorine atom. The use of monomers not bearing fluorine atoms for the synthesis of the electroactive fluorinated copolymers, such as (meth)acrylic monomers, for instance (meth)acrylic acid, decreases the number of C—F bonds present along the polymer chain. A decrease in the electroactive properties is therefore expected.

Moreover, the use of UV light to initiate the crosslinking has a considerable advantage in terms of the creation of patterns (patterning), since it is possible to selectively irradiate certain zones in order to crosslink them and to make them insoluble, while others are not. A subsequent treatment with a developing solvent (solvent etching) makes it possible to dissolve the non-irradiated parts, which results in the creation of patterns.

Furthermore, in comparison with azide chemistry, as in application WO 2013/087500, the UV dose required to obtain crosslinking is lower than that required for bis-azides. This makes it possible to avoid degradation of the properties of a multilayer device containing photosensitive layers.

### BRIEF DESCRIPTION OF THE FIGURES

FIG. 1 represents an infrared spectrogram of the films formed from the formulations 0 (bottom, continuous line) and 7 (top, broken line) using 2-butanone as solvent and the P(VDF-TrFE) copolymer as electroactive fluorinated copolymer.

FIG. 2 represents an infrared spectrogram of the films formed from the formulations 0 (bottom, continuous line) and 7 (top, broken line) using 2-butanone as solvent and the P(VDF-TrFE-CTFE) copolymer as electroactive fluorinated copolymer.

### DESCRIPTION OF EMBODIMENTS

The invention will now be described in greater detail without limitation in the description which follows.

The technical problem addressed by the present invention consists in having to make, after it has been placed on a support, or a device, a layer (a film) of electroactive fluorinated copolymer that is of use in the production of certain (opto)electronic devices, insensitive to attack by certain solvents so as to prevent dissolution or degradation thereof during the depositing, by the solvent route, of other organic or inorganic layers which are part of the device and which are deposited after the depositing of the layer of electroactive fluorinated copolymer. Another technical problem addressed by the present invention is that of the creation of patterns after depositing on a surface of a film of electroactive fluorinated copolymer on a support or device. These problems are solved by the crosslinkable composition described hereinafter.

According to a first aspect, the invention relates to a crosslinkable composition consisting of:

a) at least one electroactive fluorinated copolymer,

b) at least one (meth)acrylic monomer which is bifunctional or polyfunctional in terms of reactive double bonds,

c) at least one radical polymerization initiator,

d) at least one organic solvent, and

e) at least one additive chosen from the list: other (meth)acrylic monomers which are monofunctional in terms of reactive double bonds, agents which modify surface tension, rheology, ageing resistance, adhesion or colour, fillers and nanofillers.

According to one embodiment, said electroactive fluorinated copolymer is a copolymer of general formula P(VDF-TrFE), in which VDF represents units derived from vinylidene fluoride and TrFE represents units derived from trifluoroethylene.

According to one embodiment, the molar ratio of the VDF units to the TrFE units in the polymer is 50:50 to 85:15.

According to one embodiment, said electroactive fluorinated copolymer is a terpolymer of general formula P(VDF-TrFE-X), in which VDF represents units derived from vinylidene fluoride, TrFE represents units derived from trifluoroethylene, and X represents units derived from a third monomer bearing at least one fluorine atom, which can in particular be chosen from: tetrafluoroethylene (TFE), chlorofluoroethylene (CFE), chlorotrifluoroethylene (CTFE), hexafluoropropylene (HFP), 3,3,3-trifluoropropene, 1,3,3,3-tetrafluoropropene (or 1234ze), 2,3,3,3-tetrafluoropropene (or 1234yf), 3-chloro-2,3,3-trifluoropropene (or 1233yf), 2-chloro-3,3,3-trifluoropropene (or 1233xd), hexafluoroisobutylene, perfluorobutylethylene, pentafluoropropene and mixtures thereof. Preferably, when it is present, said third monomer is chosen from CFE and CTFE.

According to one embodiment, the molar proportion of X units in the polymer is from 0.1% to 15%, preferably from 0.5% to 13%, and more particularly preferably from 1% to 12%.

The electroactive fluorinated copolymer (a) may be homogeneous or heterogeneous, or a mixture of homogeneous and heterogeneous copolymers. A homogeneous polymer has a uniform chain structure, the statistical distribution of the comonomers not varying between the polymer chains. In a heterogeneous copolymer, the polymer chains have an average comonomer content distribution of multimodal or spread type: it therefore comprises polymer chains rich in a comonomer and polymer chains poor in said comonomer. An example of heterogeneous PVDF can be found in the document WO 2007/080338.

Although P(VDF-TrFE) and P(VDF-TrFE-X) polymers can be produced using any known process, such as emulsion polymerization, suspension polymerization and solution polymerization, it is preferable to use the process described in WO 2010/116105. This process makes it possible to obtain polymers of high molecular weight and of appropriate structuring.

Briefly, the preferred process for preparing the P(VDF-TrFE-X) polymer comprises the following steps:
charging an initial mixture of VDF and of TrFE (without X) to a stirred autoclave containing water;
heating the autoclave to a predetermined temperature, close to the polymerization temperature;
injecting a radical polymerization initiator mixed with water into the autoclave, in order to achieve a pressure in the autoclave which is preferably at least 80 bar, in order to form a suspension of the VDF and TrFE monomers in water;
injecting a second mixture of VDF, TrFE and X into the autoclave;
as soon as the polymerization reaction begins, continuously injecting said second mixture into the autoclave reactor, in order to maintain the pressure at an essentially constant level, preferably of at least 80 bar.

The radical polymerization initiator may be an organic peroxide such as a peroxydicarbonate. It is generally used in an amount of 0.1 to 10 g per kilogram of total monomer charge. The amount used is preferably from 0.5 to 5 g/kg.

The initial mixture advantageously comprises only VDF and TrFE in a proportion equal to that of the desired final polymer.

The second mixture advantageously has a composition which is adjusted such that the total composition of monomers introduced into the autoclave, including the initial mixture and the second mixture, is equal or approximately equal to the composition of the desired final polymer.

The weight ratio of the second mixture to the initial mixture is preferably from 0.5 to 2, more preferably from 0.8 to 1.6.

The implementation of this process with an initial mixture and a second mixture makes the process independent of the reaction initiation phase, which is often unpredictable.

The polymers thus obtained are in the form of a powder, without crust or skin.

The pressure in the autoclave reactor is preferably from 80 to 110 bar, and the temperature is maintained at a level of preferably from 40° C. to 60° C.

The second mixture is continuously injected into the autoclave. It can be compressed before being injected into the autoclave, for example using a compressor or two successive compressors, generally at a pressure greater than the pressure in the autoclave.

Although, according to certain embodiments, additional monomers can be used as starting materials (in a minor amount, such as for example less than 5% or less than 2% or less than 1%) and although the resulting polymer of the invention can consequently comprise a minor amount (such as for example less than 5% or less than 2% or less than 1%) of structural units other than those mentioned above, only VDF, TrFE and X are preferably used as starting materials, such that the polymer is composed only of VDF and TrFE or of VDF, TrFE and X.

However, according to one preferred embodiment, a single type of monomer X is used, and the polymer of the invention is therefore preferably a terpolymer consisting exclusively of VDF units, of TrFE units and of X units of a single type.

After synthesis, the polymer is washed and dried.

The weight-average molar mass Mw of the electroactive fluorinated copolymer (a) is preferably at least 100 000, preferably at least 200 000, and more preferably at least 300 000 or at least 400 000. It can be adjusted by modifying certain process parameters, such as the temperature in the reactor, or by adding a transfer agent.

The molar mass distribution can be estimated by SEC (Size Exclusion Chromatography) in dimethylformamide (DMF) as eluent, with a set of 3 columns of increasing porosity. The stationary phase is a styrene-DVB gel. The detection method is based on a measurement of the refractive index, and the calibration is carried out with polystyrene standards. The sample is dissolved at 0.5 g/l in DMF and filtered through a 0.45 μm nylon filter.

The molar mass can also be estimated by measurement of the melt flow index at 230° C. under a load of 5 or 10 kg according to ASTM D1238 (ISO 1133).

Moreover, the molar mass may also be characterized by a solution viscosity measurement according to ISO 1628. Methyl ethyl ketone (MEK) is a preferred solvent of copolymers and terpolymers for the determination of the viscosity index.

More generally, the molar composition of the terpolymers of the invention can be determined by various means. The conventional methods for elemental analysis of carbon, fluorine and chlorine or bromine elements result in a system of two or three independent equations having two independent unknowns (% VF2 and % TrFE, with % X=100−(% VF2+% TrFE)), which makes it possible to unambiguously calculate the composition by weight of the polymers, from which the molar composition is deduced.

Use may also be made of multinuclear, in this instance proton (¹H) and fluorine (¹⁹F), NMR techniques, by analysis of a solution of the polymer in an appropriate deuterated solvent. The NMR spectrum is recorded on an FT-NMR spectrometer fitted with a multinuclear probe. The specific signals given by the different monomers in the spectra produced according to one or other nucleus are then located. Thus, the TrFE (CFH=CF₂) unit gives, in proton NMR, a specific signal characteristic of the Hs of the CFH group (at approximately 5 ppm). It is the same for the Hs of the CH₂ group of the VF₂ (unresolved peak centred at 3 ppm). The relative integration of the two signals gives the relative abundance of the two monomers, that is to say the VDF/TrFE molar ratio.

The copolymers according to the invention are random and linear.

Advantageously, the electroactive fluorinated copolymer (component (a)) is a thermoplastic polymer which is barely or not at all elastomeric (as opposed to a fluoroelastomer). The fluoropolymers containing a high proportion of units derived from the VDF comonomer have a tendency to be thermoplastic and non-elastomeric.

The copolymers used according to the invention also preferably satisfy at least one of the criteria which describes them as electroactive polymers, in particular they have a Curie temperature of between 0 and 150° C., preferably between 10 and 140° C.

Their melting temperature is generally between 90 and 180° C., more particularly between 100 and 170° C.

The electroactive fluorinated copolymers used according to the invention have a dielectric constant, at 25° C. and at 1 kHz, of greater than 10, preferably greater than 12.

The second component (b) of the crosslinkable composition according to the invention is a (meth)acrylic monomer which is bifunctional or polyfunctional in terms of reactive double bonds. The crosslinkable composition can contain one or more monomers of this type.

Said (meth)acrylic monomer which is bifunctional or polyfunctional in terms of reactive double bonds can be a bifunctional or polyfunctional (meth)acrylic monomer or oligomer. As regards monomers that are of use in the invention, mention may be made of monomers and oligomers containing at least two reactive double bonds of (meth)acrylic type. It is these reactive double bonds which, by means of a radical polymerization initiator, will allow the polymerization and crosslinking of the (meth)acrylic network within the [electroactive fluorinated copolymer-(meth)acrylic crosslinked network] structure. As a result, any purely (meth)acrylic bifunctional or polyfunctional monomer, such as, for example, dodecane dimethacrylate, is of use in the invention.

Usually, however, the (meth)acrylic monomers or oligomers have chemical structures derived from functions other than pure alkane chemistry, such as diols, triols or polyols, polyesters, ethers, polyethers, polyurethane, epoxies, cyanurates or isocyanurates. Provided that, in their chemical structure, which is a result is mixed (not purely of hydrocarbon-based nature: of alkane type), these monomers comprise at least two (meth)acrylic functions that are reactive in radical polymerization, they become of use for the invention. Mention may thus be made, for example, of 1,3-butylene glycol di(meth)acrylate, butanediol di(meth)acrylate, 1,6-hexanediol di(meth)acrylate, alkoxylated hexanediol di(meth)acrylate, alkoxylated neopentyl glycol di(meth)acrylate, dodecyl di(meth)acrylate, cyclohexane dimethanol di(meth)acrylate, diethylene glycol di(meth)acrylate, dipropylene glycol di(meth)acrylate, linear alkane di(meth)acrylates, ethoxylated bisphenol A di(meth)acrylate, ethylene glycol di(meth)acrylate, neopentyl glycol di(meth)acrylate, tricyclodecane dimethanol diacrylate, triethylene glycol di(meth)acrylate, tetraethylene glycol di(meth)acrylate, tripropylene glycol di(meth)acrylate, ditrimethylolpropane tetra(meth)acrylate, ethoxylated pentaerythritol tetra(meth)acrylate, dipentaerythritol penta(meth)acrylate, penta(meth)acrylate ester, pentaerythritol tetra(meth)acrylate, ethoxylated trimethylolpropane tri(meth)acrylate, alkoxylated trimethylolpropane tri(meth)acrylate, trimethylolpropane tri(meth)acrylate, pentaerythritol tri(meth)acrylate, propoxylated trimethylolpropane tri(meth)acrylate, trimethylolpropane trimethacrylate, dodecanediol di(meth)acrylate, dodecane di(meth)acrylate, dipentaerythritol penta/hexa(meth)acrylate, pentaerythritol tetra(meth)acrylate, ditrimethylolpropane tetra(meth)acrylate, propoxylated glyceryl tri(meth)acrylate, propoxylated glyceryl tri(meth)acrylate, tris(2-hydroxyethyl) isocyanurate tri(meth)acrylate, polyester (meth)acrylates, polyether (meth)acrylates, polyethylene glycol (meth)acrylates, polypropylene glycol (meth)acrylates, polyurethane (meth)acrylates, epoxy (meth)acrylates, and combinations thereof.

Preferably, the bifunctional or polyfunctional (meth)acrylic monomer or oligomer may be chosen from: trimethylolpropane triacrylate (such as that sold by the company Sartomer under the reference SR351), ethoxylated trimethylolpropane triacrylate (such as that sold by the company Sartomer under the reference SR454), polyacrylate modified aliphatic urethane (such as that sold by the company Sartomer under the reference CN927).

The crosslinkable composition according to the invention also contains at least one radical polymerization initiator (component (c)). The crosslinking initiator is chosen from 2-hydroxy-2-methyl-1-phenylpropan-1-one, 2,4,6-trimethylbenzoyl-diphenylphosphine oxide, 2,4,6-trimethylbenzoylphenyl phosphinate, 1-hydroxycyclohexyl phenyl ketone, bis(2,6-dimethoxybenzoyl)-2,4,4-trimethylpentylphosphine oxide, 1-[4-(2-hydroxyethoxy)phenyl]-2-hydroxy-2-methyl-1-propan-1-one, 2,2-dimethoxy-1,2-diphenylethan-1-one and 2-methyl-1-[4-(methylthio)phenyl]-2-morpholinopropan-1-one, 2,4-diethylthioxanthone, derivatives thereof, and mixtures thereof.

As solvent (d) for the production of a solution, use is made of a solvent or a mixture of solvents chosen from those capable of dissolving the electroactive fluorinated copolymer(s), the (meth)acrylic monomer(s) (b) and the polymerization initiator(s), preferably homogeneously, so as to preferably form a transparent solution. Mention may in particular be made of: ketones, for example acetone, methyl ethyl ketone, methyl isobutyl ketone, cyclopentanone; furans, for example tetrahydrofuran; esters, for example methyl acetate, ethyl acetate, propyl acetate, butyl acetate or propylene glycol methyl ether acetate (PGMEA); carbonates, for example dimethyl carbonate; amides, such as dimethylformamide and dimethylacetamide; and sulfoxide solvents, such as dimethyl sulfoxide.

The fifth and final component of the crosslinkable composition according to the invention is represented by the additives (component (e)) chosen from the list: other (meth)acrylic monomers which are monofunctional in terms of reactive double bonds, agents for modifying the surface tension, the rheology, the ageing resistance (such as anti-UV additives of organic type such as hydroxybenzophenone or hydroxyphenylbenzotriazole or of inorganic type such as TiO₂), the adhesion (such as molecules, or oligomers or polymers bearing associative groups which may be weak acids such as carboxylic, —COOH, acids or phosphonic, —P(O)(OH)₂, acids), or the colour (such as pigments of organic type, such as phthalocyanines or anthraquinones, or of inorganic type, such as iron, copper, manganese or chromium complexes), fillers (such as TiO₂, CaCO₃, clays and zeolites of micrometric size) and nanofillers (clays and zeolites of nanometric size, carbon nanotubes). These additives are intended to improve the properties of the composition as ink or of the film formed from this ink. Preferred additives are in particular the co-solvents which modify the surface tension and/or the rheology of the ink. In particular, in the case of solutions, the compounds may be inorganic compounds that are miscible with the solvents used. The ink composition may also contain one or more additives added in order to improve a property of the ink, such as its ability to wet the surface of the electronic device, for example, or its adhesion to this surface for example.

Advantageously, the solution according to the invention does not contain compounds bearing an azide function (N₃). Compounds bearing azide functions are often explosive and toxic according to the article by H. C. Kolb et al.; Angew. Chem. Int. Ed., 2001, 40, 2004-2021.

According to one embodiment, in the crosslinkable opposition according to the invention:

i. the electroactive fluorinated copolymer (a) constitutes between 60% and 99.99% by weight, and preferably between 70% and 99% by weight, of the sum consisting of the weights of the components (a) and (b),

ii. the radical initiator (c) constitutes between 0.1% and 10% by weight, and preferably between 0.2% and 5% by weight, of the sum consisting of the weights of the components (a), (b) and (c),

iii. the additives (e) constitute from 0.01% up to less than 20% by weight of the weight of the composition.

The crosslinkable composition according to the invention comprises between 0.5% by weight and 60% by weight of non-volatile solids, and preferably between 1% by weight and 30% by weight of non-volatile solids.

According to a second aspect, the invention relates to a crosslinked film consisting of an electroactive fluorinated copolymer and of a crosslinked (meth)acrylic copolymer. Characteristically, said fluorinated copolymer is not crosslinked, and thus remains chemically non-modified, either by copolymerization with comonomers that can constitute repeating units which are reactive with respect to the crosslinking, or by chemical modification creating, on the polymer, sites which are reactive with respect to the crosslinking. In this approach, poly(functional) acrylic monomers are intimately mixed with the electroactive fluoropolymer (which is obtained by carrying out the ink (solution) process), said monomers subsequently being polymerized and crosslinked to one another. In the crosslinked film according to the invention, and unlike the prior art, the fluoropolymer ingredient is not chemically modified in order to create crosslinking sites on the fluoropolymer itself.

According to a third aspect, the invention relates to a process for preparing said crosslinked film, said process consisting of the following successive steps:
providing a crosslinkable composition according to the invention, as described above, in which said components (a), (b), (c) and (e) are dissolved in said solvent (d) so as to obtain an ink,
depositing said ink on a support, a device or a part of a device which is (opto)electronic so as to form a film,
drying said film by partial or total evaporation of the solvent, and crosslinking all or a part of said film by polymerization of the (meth)acrylic monomer(s),
in the case of the desired formation of a predefined pattern, developing said film in order to remove the non-crosslinked parts.

According to one embodiment, the radical initiator is a photoinitiator capable of activating a radical initiation via the irradiation of the ink layer deposited and “dried” (partial or total evaporation of the solvent) by light partially or completely composed of spectral cross sections which fall within the ultraviolet range, that is to say, by light, all or part of which is in the spectral range between the wavelengths 150 and 410 nm. Preferably, the activation of the initiator is obtained by irradiation comprising the wavelengths in the UVA range, in the spectral range of between 315 and 410 nm. Preferably, the activation of the initiator is obtained with irradiation comprising wavelengths at 365 nm and/or at 385 nm and/or at 405 nm. Also preferably, the irradiating dose for bringing about crosslinking is less than 20 J/cm² and more preferably less than 10 J/cm². This dose is lower than that required for bis-azides. This makes it possible to avoid degradation of the properties of a multilayer device containing photosensitive layers.

Finally, the invention also consists of the use of the layer (film) of electroactive copolymer within an (opto)electronic device, as dielectric layer, for example with high electric permittivity, of small thickness for allowing the production of field-effect transistors, or of ferroelectric memories, in particular in the printed organic electronics sector. The layer of crosslinked electroactive fluorinated copolymer with low or high electric permittivity can also be used in the fields of the production of memories, capacitors, sensors, actuators, electromechanical microsystems, haptic devices and condensers.

The term “electronic device” is intended to mean either a single electronic component, or a set of electronic components, which is (are) capable of performing one or more functions in an electronic circuit.

Preferably, in the context of the invention, the electronic device is more particularly an optoelectronic device, that is to say capable of emitting, detecting or controlling an electromagnetic radiation.

Examples of electronic devices, or where appropriate optoelectronic devices, to which the present invention relates are transistors, chips, batteries, photovoltaic cells, light-emitting diodes (LEDs), organic light-emitting diodes (OLEDs), sensors, actuators, transformers and detectors.

The electronic and optoelectronic devices are used in and integrated into numerous electronic sub-assemblies, items of equipment or apparatuses and in numerous objects and applications, such as televisions, mobile telephones, rigid or flexible screens, thin-film photovoltaic modules, lighting sources, energy converters and sensors, etc.

In the device according to the invention, said layer of film has a thickness of less than 100 μm, preferably less than 80 μm. In certain devices according to the invention, such as memories or transistors, said layer of film can have a thickness of less than 1 μm.

The surface roughness of the layer of fluoropolymer (measured with a profilometer) is preferably less than or equal to 20 nm (in Ra, quadratic mean), and more particularly less than or equal to 10 nm and even more preferably less than or equal to 7 nm. This surface roughness can be determined by a measurement of surface topography with a profilometer of alpha-step IQ type.

### EXAMPLES

The following examples illustrate the invention without limiting it. They describe the formulation of an electroactive fluoropolymer based on VDF and TrFE, in a solvent, with one or more photoinitiators and bifunctional or polyfunctional (meth)acrylic monomers which allow crosslinking, and also additives such as monofunctional (meth)acrylic monomers. The efficiency of the technical solution provided is evaluated by studying the solubility in the solvent used for the formulation of the film after UV irradiation. A film is said to be crosslinked when it is insoluble in the solvent. Dielectric constant measurements are also carried out.

### Example 1

### Preparation of the Formulation

The powder of electroactive fluoropolymer is dissolved in 2-butanone (MEK) so as to form a solution at 14% by weight. The photoinitiator(s), the bifunctional or polyfunctional (meth)acrylic monomer(s) and other monofunctional monomers (additives) are added to this solution. The formulation is homogenized by mechanical stirring for 10 minutes at ambient temperature.

### Preparation of the Film

The polymer film is prepared by applying the previously prepared solution to a glass plate. The film is dried for 1 h at ambient temperature and then 30 minutes at 60° C. in a ventilated oven.

### Crosslinking of the Film

The film, with a thickness of between 11-12 μm, is irradiated with an LED UV lamp for 15 seconds.

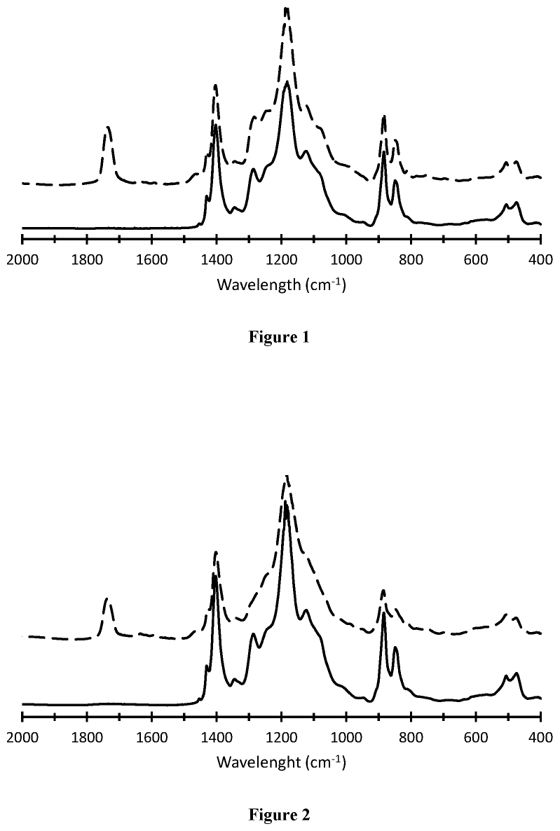

FIGS. 1 and 2 show infrared spectra of films. For the films crosslinked from formulation 7 the valence vibration band characteristic of the carbonyl moiety of the acrylate is observed at 1750 cm⁻¹. Furthermore, the bands characteristic of the tttg+tttg- and all-trans conformations associated with the electroactive properties of the polymers are always observed at 1250 and 850 cm⁻¹.

Table 1 below illustrates the influence of the composition of formulations in 2-butanone.

TABLE 1

| Formulation | 0 | 1 | 2 | 3 | 4 | 5 | 6 | 7 | 8 |
|---|---|---|---|---|---|---|---|---|---|
| Electroactive | 100 | 98.5 | 78.5 | 78.5 | 78.5 | 78.5 | 88.5 | 78.5 | 68.5 |
| fluoropolymer^{a} | | | | | | | | | |
| Photoinitiator | — | Irgacure TPO-L 1% + SpeedCure DETX 0.5% | | | | | | | |
| Bifunctional or | — | — | | SR351 | SR454 | CN927 | SR351 | SR351 | SR351 |
| polyfunctional | | | | 10% | 10% | 20% | 10% | 20% | 30% |
| (meth)acrylic monomer | | | | | | | | | |
| Monofunctional | | | SR285 | SR285 | SR285 | SR285 | SR285 | SR285 | SR285 |
| (meth)acrylic monomer | | | 20% | 10% | 10% | 1% | 1% | 1% | 1% |
| (additive) | | | | | | | | | |
| Solubility in 2-butanone | YES | YES | YES | NO | NO | NO | NO | NO | NO |
| (24 h at 22° C.) | | | | | | | | | |
| Dielectric constant ∈ | 28 | 25 | 24 | 17 | 20 | 18 | 19 | 19 | 15 |
| 22° C. and 1 kHz^{b} | | | | | | | | | |

^{a}The electroactive fluoropolymer may be: a poly(VDF-co-TrFE) copolymer, a poly(VDF-ter-TrFE-ter-CTFE) terpolymer or a poly(VDF-ter-TrFE-ter-CFE) terpolymer, of respective molar compositions 70/30, 62/30/8 and 61/31/8.
^{b}The measurements were carried out on the films prepared from the poly(VDF-ter-TrFE-ter-CTFE) terpolymer.

0: Reference formulation containing only the electroactive fluoropolymer. The UV irradiation does not degrade the polymer.

1: Influence of the photoinitiator. No influence on the solubility and the properties of the film.

2: Influence of a monofunctional acrylate (additive). It does not allow crosslinking.

3-8: Influence of various formulations with at least one bifunctional or polyfunctional (meth)acrylate. The films are crosslinked. The dielectric constant remains high and therefore satisfactory for the intended applications.

### Example 2

### Preparation of the Formulation

The powder of electroactive fluoropolymer (poly(VDF-ter-TrFE-ter-CTFE) terpolymer of molar composition 62/30/8) is dissolved in propylene glycol methyl ether acetate (PGMEA) so as to form a solution at 7% by weight. The photoinitiators (Irgacure TPO-L 1%+SpeedCure DETX 0.5%) and the bifunctional or polyfunctional (meth)acrylic monomer(s) are added to this solution. The formulation is homogenized by mechanical stirring for 10 minutes at ambient temperature.

### Preparation of the Film

The polymer film is prepared by spin coating at ambient temperature (20-25° C.) on a glass plate. The film is dried for 3 minutes at 100° C. on a hot plate.

### Crosslinking of the Film

The film, with a thickness of between 0.8 and 1.5 μm, is irradiated with an LED UV lamp at 385 nm for 15 seconds.

Table 2 below illustrates the influence of the composition of formulations (nature of the bifunctional or polyfunctional (meth)acrylic compound and concentration thereof) in PGMEA, on the solubility in PGMEA, of the thin films, formed from these formulations.

TABLE 2

| | | % of bifunctional or | |
|---|---|---|---|
| | Bifunctional or | polyfunctional | Solubility in |
| | polyfunctional | (meth)acrylic monomer | PGMEA |
| | (meth)acrylic | relative to the electroactive | (5 min |
| Formulation | monomer | fluoropolymer | at 23° C.) |
| 9 | CN966 H90 | 30 | YES |
| 10 | CN981 | 30 | NO |
| 11 | CN981 | 20 | YES |
| 12 | CN9002 | 30 | NO |
| 13 | CN9002 | 20 | YES |
| 14 | CD561 | 30 | NO |
| 15 | CD561 | 20 | NO |
| 16 | CD561 | 10 | NO |
| 17 | SR238 | 30 | YES |
| 18 | SR285 | 30 | YES |
| 19 | SR351 | 30 | NO |
| 20 | SR351 | 20 | NO |
| 21 | SR351 | 10 | YES |
| 22 | SR499 | 30 | NO |
| 23 | SR499 | 20 | NO |
| 24 | SR499 | 10 | NO |

1. Crosslinkable composition consisting of:
a) at least one electroactive fluorinated copolymer,
b) at least one (meth)acrylic monomer which is bifunctional or polyfunctional in terms of reactive double bonds,
c) at least one radical polymerization initiator,
d) at least one organic solvent, and
e) at least one additive chosen from the list: (meth)acrylic monomers which are monofunctional in terms of reactive double bonds, agents which modify surface tension, rheology, ageing resistance, adhesion or colour, fillers and nanofillers.

2. Composition according to claim 1, in which said electroactive fluorinated copolymer is a copolymer of general formula P(VDF-TrFE), in which VDF represents units derived from vinylidene fluoride and TrFE represents units derived from trifluoroethylene, the VDF:TrFE molar ratio in the polymer ranging from 50:50 to 85:15.

3. Composition according to claim 1, in which said electroactive fluorinated copolymer is a terpolymer of general formula P(VDF-TrFE-X), in which VDF represents units derived from vinylidene fluoride, TrFE represents units derived from trifluoroethylene, and X represents units derived from a third monomer bearing at least one fluorine atom.

4. Composition according to claim 3, in which the molar proportion of X units in the polymer is from 0.1% to 15%.

5. Composition according to claim 1, in which said (meth)acrylic monomer which is bifunctional or polyfunctional in terms of reactive double bonds is a monomer or an oligomer containing at least two reactive double bonds of (meth)acrylic type or a bifunctional or polyfunctional (meth)acrylic monomer or oligomer chosen from diols, triols or polyols, polyesters, ethers, polyethers, polyurethane, epoxies, cyanurates or isocyanurates.

6. Composition according to claim 5, in which said (meth)acrylic monomer is chosen from the list: dodecane dimethacrylate, 1,3-butylene glycol di(meth)acrylate, butanediol di(meth)acrylate, 1,6-hexanediol di(meth)acrylate, alkoxylated hexanediol di(meth)acrylate, alkoxylated neopentyl glycol di(meth)acrylate, dodecyl di(meth)acrylate, cyclohexane dimethanol di(meth)acrylate, diethylene glycol di(meth)acrylate, dipropylene glycol di(meth)acrylate, linear alkane di(meth)acrylates, ethoxylated bisphenol A di(meth)acrylate, ethylene glycol di(meth)acrylate, neopentyl glycol di(meth)acrylate, tricyclodecane dimethanol diacrylate, triethylene glycol di(meth)acrylate, tetraethylene glycol di(meth)acrylate, tripropylene glycol di(meth)acrylate, ditrimethylolpropane tetra(meth)acrylate, ethoxylated pentaerythritol tetra(meth)acrylate, dipentaerythritol penta(meth)acrylate, penta(meth)acrylate ester, pentaerythritol tetra(meth)acrylate, ethoxylated trimethylolpropane tri(meth)acrylate, alkoxylated trimethylolpropane tri(meth)acrylate, trimethylolpropane tri(meth)acrylate, pentaerythritol tri(meth)acrylate, propoxylated trimethylolpropane tri(meth)acrylate, trimethylolpropane trimethacrylate, dodecanediol di(meth)acrylate, dodecane di(meth)acrylate, dipentaerythritol penta/hexa(meth)acrylate, pentaerythritol tetra(meth)acrylate, ditrimethylolpropane tetra(meth)acrylate, propoxylated glyceryl tri(meth)acrylate, propoxylated glyceryl tri(meth)acrylate, tris(2-hydroxyethyl) isocyanurate tri(meth)acrylate, polyester (meth)acrylates, polyether (meth)acrylates, polyethylene glycol (meth)acrylates, polypropylene glycol (meth)acrylates, polyurethane (meth)acrylates, epoxy (meth)acrylates, and combinations thereof.

7. Composition according to claim 1, in which said solvent is chosen from: ketones, furans, esters, carbonates, amides and sulfoxides.

8. Composition according to claim 1, in which said radical polymerization initiator is chosen from 2-hydroxy-2-methyl-1-phenylpropan-1-one, 2,4,6-trimethylbenzoyl-diphenylphosphine oxide, 2,4,6-trimethylbenzoylphenyl phosphinate, 1-hydroxycyclohexyl phenyl ketone, bis(2,6-dimethoxybenzoyl)-2,4,4-trimethylpentylphosphine oxide, 1-[4-(2-hydroxyethoxy)phenyl]-2-hydroxy-2-methyl-1-propan-1-one, 2,2-dimethoxy-1,2-diphenylethan-1-one and 2-methyl-1-[4-(methylthio)phenyl]-2-morpholinopropan-1-one, 2,4-diethylthioxanthone, derivatives thereof, and mixtures thereof.

9. Composition according to claim 1, in which:
i. the electroactive fluorinated copolymer (a) constitutes between 60% and 99.99% by weight of the sum consisting of the weights of the components (a) and (b),
ii. the radical initiator (c) constitutes between 0.1% and 10% by weight of the sum consisting of the weights of the components (a), (b) and (c),
iii. the additives (e) constitute from 0.01% up to less than 20% by weight of the weight of the composition.

10. Crosslinked film consisting of at least one non-crosslinked electroactive fluorinated copolymer according to claim 2 and one crosslinked (meth)acrylic copolymer obtained by crosslinking a crosslinkable composition consisting of:
a) at least one electroactive fluorinated copolymer,
b) at least one (meth)acrylic monomer which is bifunctional or polyfunctional in terms of reactive double bonds,
c) at least one radical polymerization initiator,
d) at least one organic solvent, and
e) at least one additive chosen from the list: (meth)acrylic monomers which are monofunctional in terms of reactive double bonds, agents which modify surface tension, rheology, ageing resistance, adhesion or colour, fillers and nanofillers,
in which said (meth)acrylic monomer which is bifunctional or polyfunctional in terms of reactive double bonds is a monomer or an oligomer containing at least two reactive double bonds of (meth)acrylic type or a bifunctional or polyfunctional (meth)acrylic monomer or oligomer chosen from diols, triols or polyols, polyesters, ethers, polyethers, polyurethane, epoxies, cyanurates or isocyanurates.

11. Process for preparing a crosslinked film, said process consisting in:
providing a crosslinkable composition according to claim 1, in which said components (a), (b), (c) and (e) are dissolved in said solvent (d) so as to obtain an ink,
depositing said ink on a support, a device or a part of a device which is (opto)electronic so as to form a film,
drying said film by partial or total evaporation of the solvent, and
crosslinking all or a part of said film by polymerization of the (meth)acrylic monomer(s),
in the case of the desired formation of a predefined pattern, developing said film in order to remove the non-crosslinked parts.

12. Process according to claim 11, in which said radical initiator is a photoinitiator capable of being activated by light partially or completely composed of the spectral cross sections between the wavelengths 150 and 410 nm.

13. Process according to claim 11, in which the irradiating dose for bringing about the crosslinking of the film is less than 20 J/cm².

14. (Opto)electronic device comprising, as dielectric layer, at least one layer of the film prepared according to the process described in claim 11.

15. Device according to claim 14, comprising a stack of one or more layers deposited on said layer of film.

16. Device according to claim 14, chosen from field-effect transistors and ferroelectric memories.

17. Device according to claim 14, chosen from actuators, haptic devices, condensers, diodes, sensors, and electromechanical microsystems.
